(19) United States
(12) Patent Application Publication
(10) Pub. No.: US 2009/0020767 A1
(43) Pub. Date: Jan. 22, 2009

(54) Active Matrix Substrate

(75) Inventor: Han-Tung Hsu, Padeh City (TW)

Correspondence Address: INTELLECTUAL PROPERTY LAW GROUP LLP, 12 SOUTH FIRST STREET, SUITE 1205, SAN JOSE, CA, 95113, US

(73) Assignee: CHUNGHWA PICTURE TUBES, LTD, Padeh City (TW)

(21) Appl. No.: 12/014,752

(22) Filed: Jan. 15, 2008

(30) Foreign Application Priority Data
Jul. 17, 2007 (TW) 96125959

(51) Int. Cl. H01L 29/04

(52) U.S. Cl. 257/88; 257/E29.003

(57) ABSTRACT

An active matrix substrate is provided. Within the field of the probe contact area of the pad portion, a buffer layer is arranged on a pad in order to increase the thickness of the pad portion; or, to hollow out the pad and form an opening within the probe contract area. Thus, the probe will not touch the pad directly even if the probe is pressed inadequately to pierce the conductive layer. As a result, the substrate structure can prevent the metallic pad from chemically reacting with the mist or the air, and further to avoid an electrical erosion state. Therefore the signal of the probe can still be transmitted through the conductive layer.

### CROSS-REFERENCE TO RELATED APPLICATIONS

This application claims foreign priority under 35 U.S.C. § 119 to Taiwanese Patent Application no. 96125959, filed in Taiwan, Republic of China on Jul. 17, 2007, the entire contents of which are hereby incorporated by reference.

### BACKGROUND OF THE INVENTION

1. Field of the Invention

The present invention relates to a liquid crystal display apparatus. More particularly, the present invention relates to an active matrix substrate of the liquid crystal display apparatus which can avoid the electrical erosion state.

2. Description of the Prior Art

For display manufacturers, the panel inspection is the most important procedure after the whole processes. The display manufacturers will inspect the quality of the finished products before the finished products are purchased on the market to make sure the consumers will not receive imperfect products. Thus, all display manufacturers will process the panel inspection procedure after the whole processes or the panel assembling are finished. The purpose of the panel inspection is to check the appearance of the panel and the light-on testing of the panel, and the light-on testing is to inspect the dot defects (light dot/dark dot) and the line defects. During the panel inspection, the probe is utilized to transmit the signal into the panel to make sure the data line and the gate line can work normally to transmit the signal.

FIG. 1 is a diagram to illustrate the liquid crystal display apparatus according to a prior art. As shown in FIG. 1, the active matrix substrate of the liquid crystal display apparatus includes: a substrate 22; an active area 222; a peripheral circuit area 224 positioned around the active area 222; a plurality of pixels 226 arranged as an array within the active area 222 of the substrate 22; a plurality of first wires 228 arranged on the substrate 22 wherein the first wires 228 extend toward the active area 222 from the peripheral circuit area 224, and electrically connected with the pixels 226 respectively; a plurality of first pad portions 230 arranged on the gate side of the substrate 22; a plurality of second wires 232 arranged on the substrate 22, wherein the second wires 232 extend toward the active area 222 from the peripheral circuit area 224, and electrically connected with the pixels 226 respectively; a plurality of second pad portions 234 arranged on the source side of the substrate 22. Moreover, the first wires 228 and the second wires 232 are respectively arranged on the gate side and the source side of the substrate 22. FIG. 2A is the top side view diagram of the pad portion and diagram, and FIG. 2B shows the sectional view of the portion indicated by the section lines A-A1 in FIG. 2A according to the prior art. The conventional pad portion includes a gate electrode layer 14 arranged on a substrate 12, a gate insulation layer 15 and a protection layer 16 arranged on the gate electrode layer 14, and a conductive layer 18 (such as a pixel electrode layer) covering the pad portion. During the panel inspection, the probe touches the conductive layer 18 (such as Indium Tin Oxide or Indium Zinc Oxide) of the probe contact area 10 directly, and then transmits the signal to the source/drain electrode layer (not shown) or the gate electrode layer 14 by the conductivity of the conductive layer 18 and the metallic gate electrode layer 14 so as to drive the display electrode (not shown). However, because the depth of the conductive layer 18 is quite thin, the probe will pierce the conductive layer 18 and then directly touch the gate electrode layer 14 in the situation of the probe being pressed too much to result in the metal of the pad portion being exposed to the air. However, the gate electrode layer 14 is made of a metal which has better activity. As a result, the exposed pad portion will react with the mist or the air easily. In addition, due to the length difference between each probe in the probe module, the piercing depth is different from each other when the probe module pierces into the pad portion. Some probes touch the conductive layer 18 on the surface, and some pierce through the conductive layer 18 to directly touch the gate electrode layer 14. In this way, the metal of the pad portion is exposed under the air, and chemically reacts with the mist or the air to cause an electrical erosion state. Further, the gate electrode layer 14 will be eroded during light-on procedure. Therefore, the path of the signal is broken, and the panel inspection will cause defects, such as the dot defects or the line defects.

### SUMMARY OF THE INVENTION

One object of the present invention is to provide an active matrix substrate, and the active matrix substrate has a buffer layer within the probe contact area of the pad portion to increase the thickness of the pad portion so as to avoid the probe touching the pad directly to prevent the electrical erosion state.

Another object of the present invention is to provide an active matrix substrate, which has a patterned pad portion. A portion of pad of the pad is hollowed out, so that there is no pad within the probe contact area. As a result, the electrical erosion state will not happen even though the probe is pressed too much.

Accordingly, the present invention is to provide an active matrix substrate to avoid the process of the panel inspection damaging the metal of the pad portion on the panel. The active matrix substrate can avoid the metal of the pad portion from being exposed under the air so as to effectively prevent the occurrence of the electrical erosion, to dramatically increase the yield of the panel, and further to enhance the product competitiveness.

In accordance with the above objects of the present invention, an active matrix substrate is provided. An active area and a peripheral circuit area are defined on the active matrix substrate, wherein the peripheral circuit area is located around the active area. The active matrix substrate includes: a substrate; a plurality of pixels arranged as an array within the active area of the substrate; a plurality of first wires arranged on the substrate, wherein the first wires extend toward the active area from the peripheral circuit area and electrically connected with the pixels respectively; a plurality of first pads arranged within the peripheral circuit area of the substrate and electrically connected with the first wires respectively; a patterned dielectric layer covering the first pads, wherein the patterned dielectric layer includes a plurality of openings positioned on the first pads; a first buffer layer positioned in the openings and configured on the first pads; a plurality of conductive layers covering the patterned dielectric layers on the first pads respectively, the first buffer layer and the exposed first pads; a plurality of second wires arranged on the substrate wherein the second wires extend toward the active area from the peripheral circuit area and electrically connected with the pixels respectively; and a plurality of second pads arranged within the peripheral circuit area of the substrate and electrically connected with the second wires respectively.

In accordance with the above objectives of the present invention, an active matrix substrate is provided. An active area and a peripheral circuit area are defined on the active matrix substrate, wherein the peripheral circuit area is located around the active area. The active matrix substrate includes: a substrate; a plurality of pixels arranged as an array within the active area of the substrate; a plurality of first wires arranged on the substrate wherein the first wires extend toward the active area from the peripheral circuit area and electrically connected with the pixels respectively; a plurality of first patterned pads arranged within the peripheral circuit area of the substrate and electrically connected with the first wires respectively, wherein the first patterned pads include at least one first opening; a patterned dielectric layer covered the first patterned pads wherein the patterned dielectric layer includes a plurality of second openings wherein at least one second opening connects the first opening, and part of the second openings expose the first pattern pads; a plurality of conductive layers respectively covering the patterned dielectric layer, wherein the patterned dielectric layer is positioned on the first patterned pads, and the plurality of conductive layers connect the first patterned pads through the first opening and the second openings; a plurality of second wires arranged on the substrate wherein the second wires extend toward the active area from the peripheral circuit area and electrically connected with the pixels respectively; and a plurality of second patterned pads arranged within the peripheral circuit area and electrically connected with the second wires respectively.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a diagram to illustrate the liquid crystal display apparatus according to a prior art;

FIG. 2A is a top side view diagram of the pad portion according to a prior art;

FIG. 2B is a sectional-view diagram of the portion indicated by the section lines A-A1 in FIG. 2A;

FIG. 3A is a top side view diagram of the first pad portion on the gate side in accordance with an embodiment of the present invention;

FIG. 3B is a sectional-view diagram of the first pad portion on the gate side indicated by the section lines B-B1 in FIG. 3A;

FIG. 3C is a sectional-view diagram of the first pad portion on the gate side indicated by the section lines B-B1 in FIG. 3A in accordance with a second embodiment of the present invention;

FIG. 3D is a sectional-view diagram of the first pad portion on the gate side indicated by the section lines B-B1 in FIG. 3A in accordance with a third embodiment of the present invention;

FIG. 4A is a top side view diagram of the first pad portion on the gate side in accordance with a fourth embodiment of the present invention;

FIG. 4B is a sectional-view diagram of the portion indicated by the section lines C-C1 in FIG. 4A;

FIG. 5A is a top side view diagram of the first pad portion on the gate side in accordance with a fifth embodiment of the present invention;

FIG. 5B is a sectional-view diagram of the first pad portion on the gate side indicated by the section lines D-D1 in FIG. 5A; and

FIG. 6 is a sectional-view diagram of the second pad portion on the source side in accordance of a sixth embodiment of the present invention.

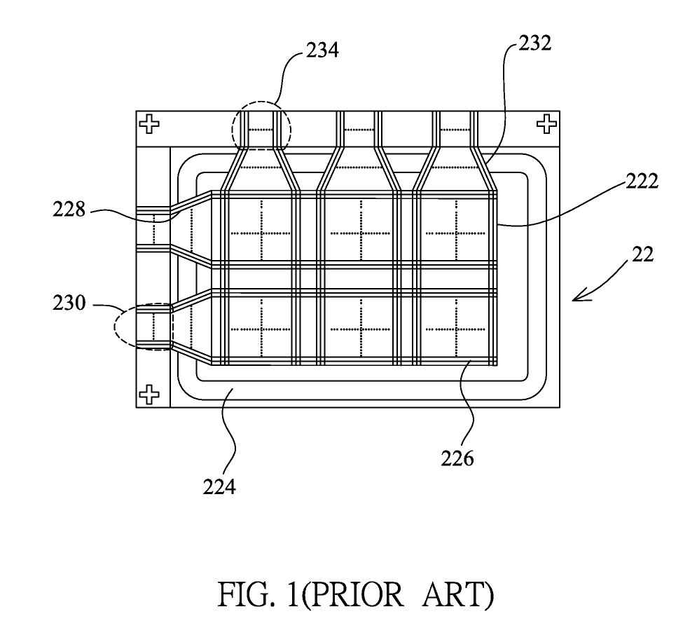

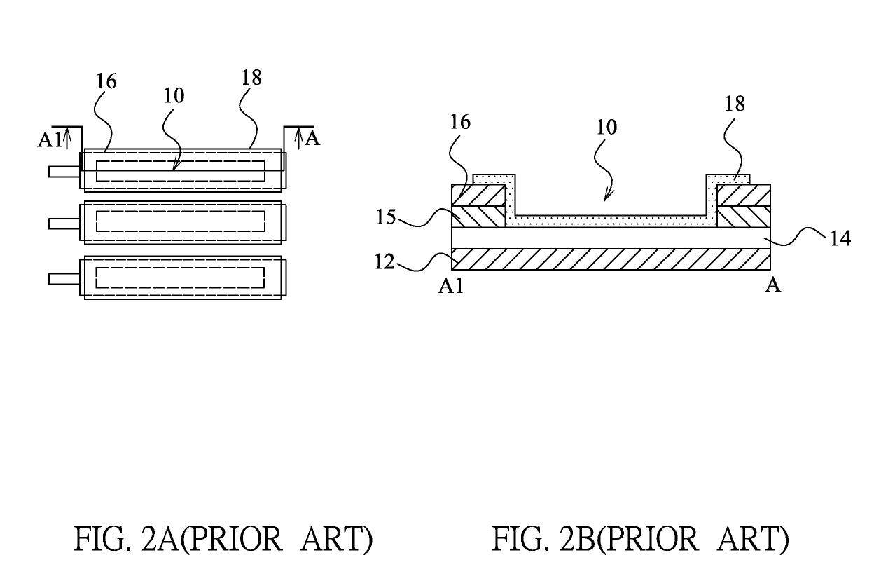

### DETAILED DESCRIPTION OF THE INVENTION

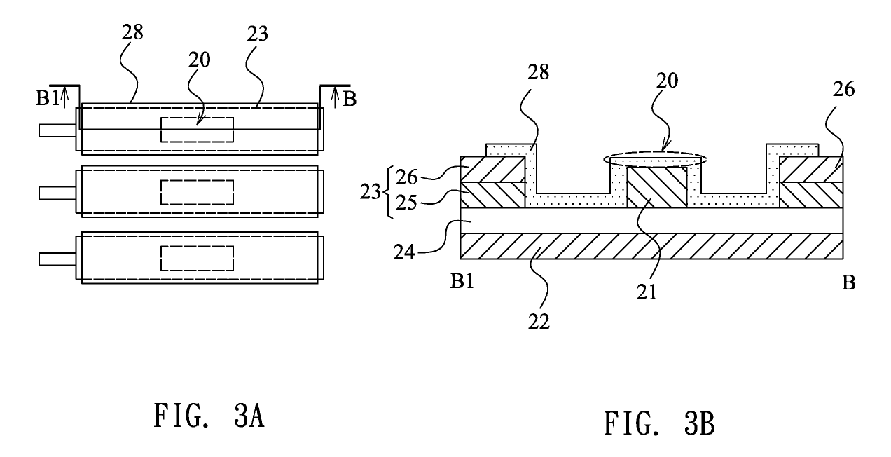

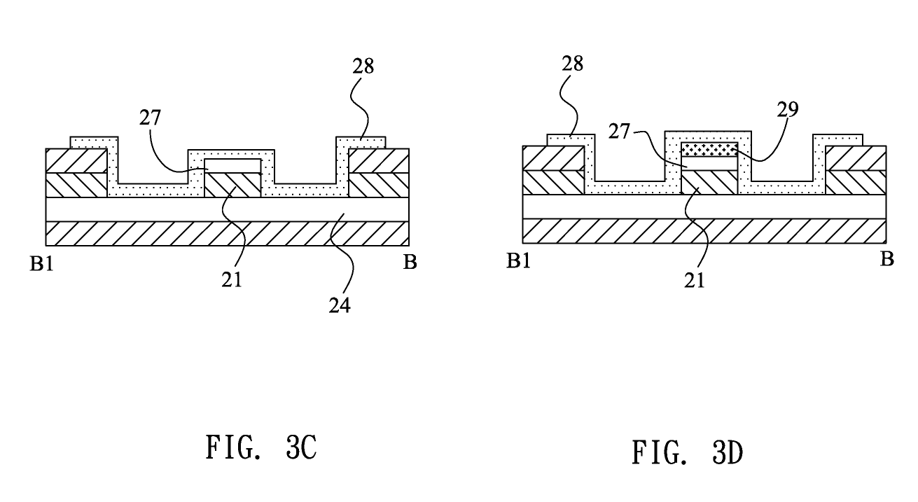

FIG. 3A is top side view diagram of the first pad portion on the gate side, and FIG. 3B shows sectional-view of the first pad portion on the gate side indicated by the section lines B-B1 in FIG. 3A in accordance with an embodiment of the present invention. In the embodiment, the first pad portion includes: a first pad 24, such as a gate electrode layer (GE layer), arranged within the peripheral circuit area of the substrate 22 and electrically connected with the first wire; a patterned dielectric layer 23 covers the first pad 24 wherein the patterned dielectric layer 23 includes a gate dielectric layer 25 and a protection layer 26, part of the gate dielectric layer 25 is positioned between the first pad 24 and the protection layer 26, the patterned dielectric layer 23 has a plurality of openings positioned on the first pad 24 and the openings are formed within the gate dielectric layer 25 and the protection layer 26; a first buffer layer 21 positioned within each opening and located on the first pad 24, in this embodiment, the first buffer layer 21 and the gate dielectric layer 25 are the same layers; and a plurality of conductive layers 28, such as Indium Tin Oxide (ITO) or Indium Zinc Oxide (IZO), respectively covering the patterned dielectric layers 23 which are positioned on the first pad 24, the first buffer layer 21, and the exposed first pad 24. Shown in FIG. 3A and FIG. 3B, when first buffer layer 21 is taken as a probe contact area 20, the thickness of the probe contact area 20 is dramatically increased. Due to the protection of the first buffer layer 21, the probe will not pierce the first pad 24 to induce the electrical erosion state even when the probe is pressed too much when the probe touches the conductive layer 28 of the probe contact area 20 during the panel inspection. Next, the signal can be transmitted to the GE layer (not shown) to drive the display electrode (not shown) through the conductive layer 28 and the first pad 24, so as to achieve the purpose of the panel inspection.

FIG. 3C is a sectional-view diagram of the first pad portion on the gate side indicated by the section lines B-B1 in FIG. 3A in accordance with a second embodiment of the present invention. Shown in FIG. 3C, the first pad portion further includes a second buffer layer 27 positioned between the first buffer layer 21 and the conductive layer 28, wherein the material of the second buffer layer 27 includes amorphous silicon. In this embodiment, the arrangement of the first buffer layer 21 and the second buffer layer 27 increases the thickness of the probe contact area, thus, the first buffer layer 21 and the second buffer layer 27 can avoid the probe piercing the first pad 24 due to the inadequate force and further to avoid the electrical erosion state.

FIG. 3D is a sectional-view diagram of the first pad portion on the gate side indicated by the section lines B-B1 in FIG. 3A in accordance with a third embodiment of the present invention. The difference between this embodiment and the previous embodiments is that the first pad portion of this embodiment further includes a third buffer layer 29 positioned between the second buffer layer 27 and the conductive layer 28, wherein the material of the third buffer layer 29 includes metal. Thus, the first pad portion of this embodiment provides better protection due to the additional arrangement of the first buffer layer 21, the second buffer layer 27 and the third buffer layer 29.

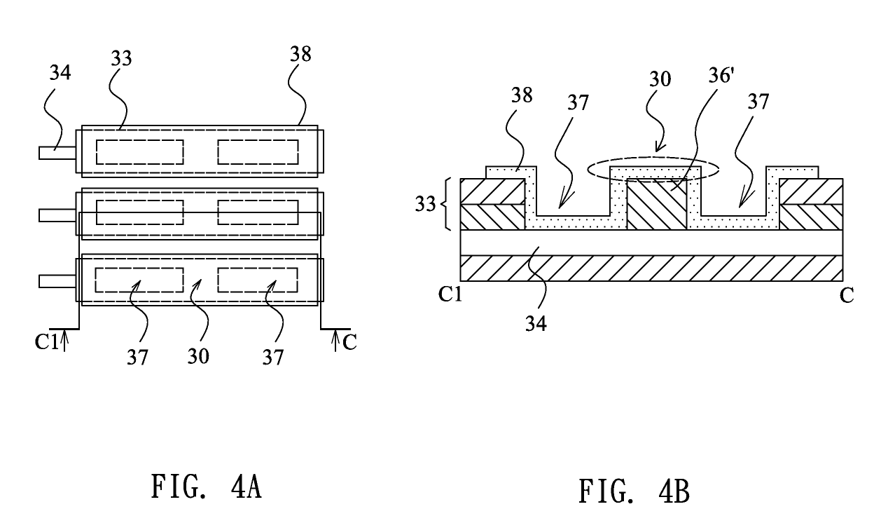

FIG. 4A is top side view diagram of the first pad portion on the gate side and FIG. 4B is a sectional-view diagram of the portion indicated by the section lines C-C1 in FIG. 4A in accordance with the fourth embodiment of the present invention. The difference between this embodiment and the previous embodiments is that the first pad 34 of this embodiment arranges a first buffer layer 36′ as a probe contact area 30 to increase the thickness of the first pad 34, wherein the first buffer layer 36′ and the patterned dielectric layer 33 are the same layers. In this embodiment, in order to have no contact hole within the probe contact area 30, the contact hole 37 of the first pad portion is divided into two parts during the pattern layout process. Due to the first buffer layer 36′ being an insulating material, the signal transmits through the conductive layer 38 when the probe touches the probe contact area 30, and the probe will not directly touch the first pad 34 even if the probe is pressed inadequately, so as to achieve the goal to avoid the electrical erosion state.

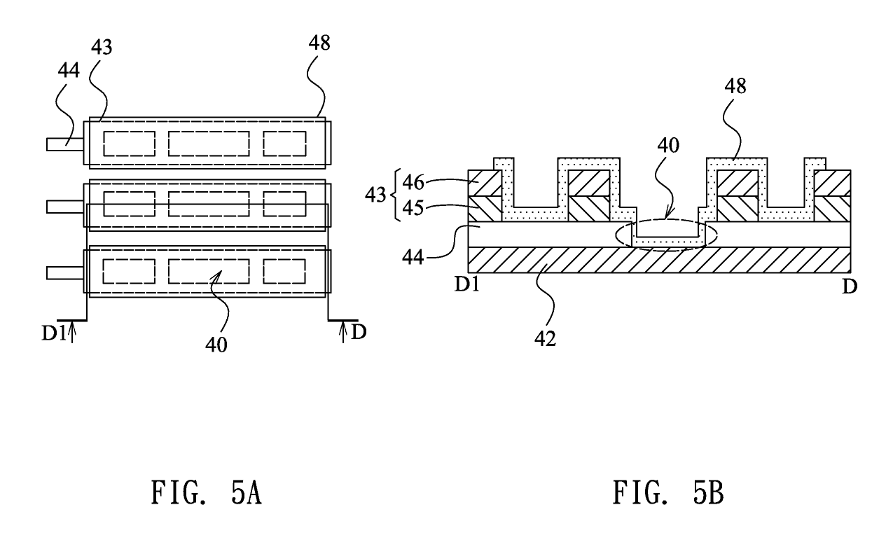

FIG. 5A is top side view diagram of the first pad portion on the gate side and FIG. 5B is a sectional-view diagram of the first pad portion on the gate side indicated by the section lines D-D1 in FIG. 5A in accordance with the fifth embodiment of the present invention. Shown in FIG. 5A and FIG. 5B, the first pad portion includes: a first patterned pad 44, such as a GE layer in this embodiment, positioned within the peripheral circuit area of the substrate 42 and electrically connected with the first wire, wherein the first patterned pad 44 includes at least one first opening, and the first opening is taken as a probe contact area 40; a patterned dielectric layer 43 covering the first patterned pad 44, wherein the patterned dielectric layer 43 includes a gate dielectric layer 45, a protection layer 46 and a plurality of second openings, wherein at least one second opening connects the first opening and part of the second openings expose the first patterned pad 44; and a plurality of conductive layers 48 respectively covering the patterned dielectric layer 43 which is positioned on the first patterned pad 44, and the conductive layers 48 connect with the first patterned pad 44 through the first opening and the second openings. In this embodiment, the signal came from the probe will be transmitted through the conductive layer 48, such as ITO or IZO in this embodiment, rather than via the first patterned pad 44, thus, even though the probe is over pressed to pierce the conductive layer 48, the probe within the probe contact area 40 will not directly touch and damage the first patterned pad 44 during the panel inspection, so as to avoid the electrical erosion state.

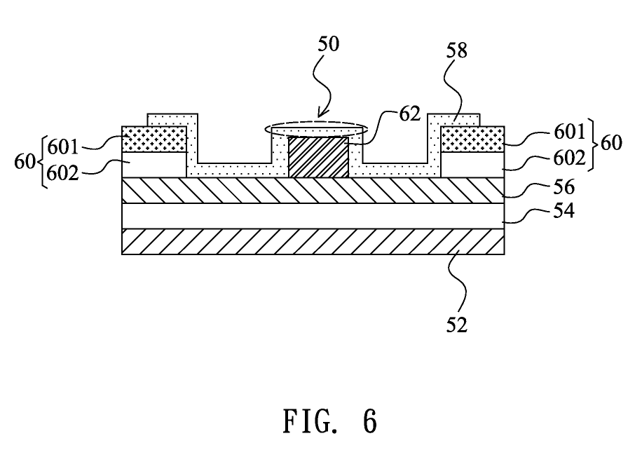

FIG. 6 is a sectional-view diagram of the second pad portion on the source side in accordance with the sixth embodiment of the present invention. In this embodiment, the second pad portion includes: a second pad positioned within the peripheral circuit area of the substrate 52 and electrically connected with the second wire respectively wherein the second pad is a combination of the gate insulation layer (GI layer) 54 and the source/drain electrode layer (SD layer) 56, and the GI layer 54 is positioned between the substrate 52 and the SD layer 56; a patterned dielectric layer 60 covering the second pad, wherein the patterned dielectric layer 60 includes a gate dielectric layer 601 and a protection layer 602, and part of the gate dielectric layer 601 is positioned between the second pad and the protection layer 602, and the patterned dielectric layer 60 has a plurality of openings positioned on the second pad; a first buffer layer 62 positioned within the openings and arranged on the second pad, wherein the first buffer layer 62 and the gate dielectric layer 601 are the same layers; and a plurality of conductive layers 58, such as ITO or IZO in this embodiment, covering the patterned dielectric layer 60 which is positioned on the second pad, the first buffer layer 62, and the exposed second pad. Shown in FIG. 6, the first buffer layer 62 is arranged as a probe contact area 50 to increase the thickness of the second pad portion. Thus, even though the probe pierces the conductive layer 58 during the panel inspection, there is still a first buffer layer 62 to serve as a buffer to avoid the probe piercing the second pad to prevent the electrical erosion state. And, the signal coming from the probe will transmit through the conductive layer 58 to the display electrode (not shown) to achieve the goal of the panel inspection.

In addition, the design of the buffer layer on the second pad portion of the source side is the same as the first pad portion of the gate side, and the detail will not be described here again.

To sum up the foregoing descriptions, for an active matrix substrate in accordance with this invention, within the field of the probe contact area of the first pad portion of the gate side, a buffer layer is arranged on a first pad to be the probe contact area so as to increase the thickness of the first pad portion. A first patterned pad is formed by hollowing out an opening within the first pad and the opening is taken as the probe contact area. Thus, the probe will not directly touch the first pad/first patterned pad even though the probe is pressed too much to pierce the conductive layer. As a result, the substrate structure can prevent the metal part of the first pad/first patterned pad from chemically reacting with the mist or the air and further avoid an electrical erosion state, and the signal of the probe still can transmit through the conductive layer.

To sum up the foregoing descriptions, for an active matrix substrate in accordance with this invention, within the field of the probe contact area of the second pad portion of the source side, a buffer layer is arranged on a second pad to increase the thickness of the second pad portion, or a second patterned pad is formed by hollowing out the second pad within the probe contact area. Thus, the probe will not directly touch the second pad/second patterned pad even though the probe is pressed so much as to pierce the conductive layer. As a result, the substrate structure can prevent the metal part of the second pad/second patterned pad from chemically reacting with the mist or the air and further avoid the electrical erosion state, and the signal of the probe still can transmit through the conductive layer.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. An active matrix substrate comprising an active area and a peripheral circuit area located around the active area, and the active matrix substrate further comprising:
a substrate;
a plurality of pixels arranged as an array within the active area of the substrate;
a plurality of first wires arranged on the substrate wherein the first wires extend toward the active area from the peripheral circuit area and respectively electrically connected with the pixels;
a plurality of first pads arranged within the peripheral circuit area of the substrate and electrically connected with the first wires respectively;
a patterned dielectric layer covering the first pads wherein the patterned dielectric layer comprises a plurality of openings positioned on the first pads;
a first buffer layer positioned in the openings and configured on the first pads;
a plurality of conductive layers covering the patterned dielectric layers on the first pads respectively, the first buffer layer, and the exposed first pads;
a plurality of second wires arranged on the substrate wherein the second wires extend toward the active area from the peripheral circuit area and electrically connected with the pixels respectively; and
a plurality of second pads arranged within the peripheral circuit area of the substrate and electrically connected with the second wires respectively.

2. The active matrix substrate according to claim 1, wherein the patterned dielectric layer comprises a gate dielectric layer and a protection layer wherein part of the gate dielectric layer is positioned between the first pads and the protection layer, and the openings are formed within the gate dielectric layer and the protection layer.

3. The active matrix substrate according to claim 2, wherein the first buffer layer and the gate dielectric layer are the same layers.

4. The active matrix substrate according to claim 3, further comprising a second buffer layer arranged between the first buffer layer and the conductive layers.

5. The active matrix substrate according to claim 4, wherein the material of the second buffer layer includes amorphous silicon.

6. The active matrix substrate according to claim 4, further comprising a third buffer layer arranged between the second buffer layer and the conductive layers.

7. The active matrix substrate according to claim 6, wherein the material of the third buffer layer includes metal.

8. The active matrix substrate according to claim 1, wherein the material of the conductive layers is indium tin oxide or indium zinc oxide.

9. The active matrix substrate according to claim 1, wherein the first buffer layer and the patterned dielectric layer are the same layers.

10. An active matrix substrate comprising an active area and a peripheral circuit area located around the active area, and the active matrix substrate further comprising:
a substrate;
a plurality of pixels arranged as an array within the active area of the substrate;
a plurality of first wires arranged on the substrate wherein the first wires extend toward the active area from the peripheral circuit area and electrically connected with the pixels respectively;
a plurality of first patterned pads arranged within the peripheral circuit area of the substrate and respectively electrically connected with the first wires wherein the first patterned pads comprise at least one first opening;
a patterned dielectric layer covering the first patterned pads wherein the patterned dielectric layer comprises a plurality of second openings wherein at least one second opening connects the first opening, and part of the second openings expose the first pattern pads;
a plurality of conductive layers respectively covering the patterned dielectric layer, wherein the patterned dielectric layer is positioned on the first patterned pads, and the plurality of conductive layers connect the first patterned pads through the first opening and the second openings;
a plurality of second wires arranged on the substrate wherein the second wires extend toward the active area from the peripheral circuit area and electrically connected the pixels respectively; and
a plurality of second patterned pads arranged within the peripheral circuit area and electrically connected the second wires respectively.

11. The active matrix substrate according to claim 10, wherein the patterned dielectric layer comprises a gate dielectric layer and a protection layer, part of the gate dielectric layer is positioned between the first patterned pads and the protection layer.

12. The active matrix substrate according to claim 10, wherein the material of the conductive layers is indium tin oxide or indium zinc oxide.
